(19) United States
(12) Patent Application Publication
(10) Pub. No.: US 2025/0246223 A1
(43) Pub. Date: Jul. 31, 2025

(54) APPARATUS AND METHOD FOR ADAPTIVELY ADJUSTING REFRESH TIMING OF CIM BASED ON EDRAM

(71) Applicant: UIF (University Industry Foundation), Yonsei University, Seoul (KR)

(72) Inventors: Seong-Ook JUNG, Seoul (KR); Dong-Gyun HA, Seoul (KR); Do-Han KIM, Seoul (KR)

(21) Appl. No.: 18/986,202

(22) Filed: Dec. 18, 2024

(30) Foreign Application Priority Data
Dec. 22, 2023 (KR) 10-2023-0189888

(51) Int. Cl. G11C 11/406; G11C 7/06

(52) U.S. Cl. CPC G11C 11/40615; G11C 7/06; G11C 2211/406

(57) ABSTRACT

An apparatus for adaptively adjusting refresh timing of a CIM based on eDRAM includes a replica array including a plurality of replica MAC arrays, each having replica cells arranged in a direction and number according to the direction and number in which memory cells performing MAC operations together in a CIM cell array are arranged and a refresh determination module that compares voltage levels of signals output from each of the plurality of replica MAC arrays with MAC operation results according to weights stored in replica cells of the plurality of replica MAC arrays and activates a refresh enable signal for refreshing memory cells of the CIM cell array.

### CROSS-REFERENCE TO RELATED APPLICATIONS

This application claims priority under 35 U.S.C. § 119 (a) to Korean Patent Application No. 10-2023-0189888, filed on Dec. 22, 2023, with the Korean Intellectual Property Office, the disclosure of which is incorporated herein in its entirety by reference.

### BACKGROUND

### 1. Technical Field

The present disclosure relates to an apparatus and method for adjusting refresh timing of a CIM based on eDRAM, and more particularly, to an apparatus and method for adjusting refresh timing of a CIM based on eDRAM that adaptively adjusts a refresh time by considering a MAC operation.

### 2. Description of the Related Art

In the case of the existing von Neumann architecture, the processor and memory were separated, and the processor read the data stored in the memory and performed operations, so there were limitations in improving energy efficiency and operation speed according to data access and transmission. In addition, recently, due to the advancement of artificial neural network technology, MAC (Multiply-Accumulate) operations must be performed on a large scale between input data and weights in DNN (Deep Neural Network), etc., so techniques that can improve energy efficiency and operation speed are required.

Accordingly, the CIM (Compute-In-Memory or In-Memory Compute) architecture was proposed to maximize efficiency by performing operations using the memory that stores data. In the CIM architecture, the memory that stores data performs operations directly without transmitting data to the processor, thereby overcoming the limitations of the existing von Neumann architecture and performing operations at low power and high speed.

Due to recent technological advancements, the complexity of neural network models has increased, which has led to a significant increase in the amount of data that must be processed in CIM. However, SRAM, which is mainly used as a memory cell in conventional CIM, requires a large cell size, which poses a problem in that it is difficult to satisfy the required CIM capacity.

Due to this problem, embedded DRAM (hereinafter “eDRAM”) with a smaller cell size than SRAM is increasingly being used in CIM. In eDRAM, data is stored in a storage node (SN), which is a floating node. However, there is a problem that the data stored in the storage node (SN) may change in value due to leakage. Therefore, a refresh operation that periodically rewrites the data stored in eDRAM is required.

Existing memory devices that require refresh operations, including CIM, suppress power consumption increases due to refresh operations by performing refreshes as slowly as possible at a level where the data in the memory cell does not change. At this time, most memory devices adjust the refresh timing based on the data retention time (hereinafter “DRT”), which indicates the time from when data is stored in the memory cell until the value of the stored data is flipped. In other words, it means the time until data stored as 1 changes to 0 or data stored as 0 changes to 1.

However, CIM performs MAC operation in the form of cumulative sum of data values stored in multiple memory cells, and at this time, it performs MAC operation in an analog manner based on the amount of charge charged in the memory cell, not in a digital manner. As a result, even if the data stored in each memory cell has not reached the DRT and the value has not changed, an error may occur in the MAC operation result due to a change in the amount of charge charged to the memory cell. Therefore, when performing a refresh operation based on the DRT of the memory cell, there is a problem that an error may occur in the MAC operation result of CIM, even if the data stored in the memory cell is maintained normally.

### SUMMARY

An object of the present disclosure is to provide an apparatus and method for adaptively adjusting refresh timing of a CIM based on eDRAM that adaptively adjusts refresh timing so that an error does not occur in a MAC operation result.

Another object of the present disclosure is to provide an apparatus and method for adaptively adjusting refresh timing of a CIM based on eDRAM that can detect whether a MAC operation error is likely to occur based on a replica array and generate a refresh command.

According to one embodiment of the present disclosure, an apparatus for adaptively adjusting refresh timing of a CIM based on eDRAM includes: a replica array including a plurality of replica MAC arrays, each having replica cells arranged in a direction and number according to the direction and number in which memory cells performing MAC operations together in a CIM cell array are arranged; and a refresh determination module that compares voltage levels of signals output from each of the plurality of replica MAC arrays with MAC operation results according to weights stored in replica cells of the plurality of replica MAC arrays and activates a refresh enable signal for refreshing memory cells of the CIM cell array.

In the replica array, one of the plurality of replica MAC arrays may be a replica MAC signal generation array in which weights of the same data values are stored in all of the replica cells to generate a replica MAC signal, and the other one may be a replica reference signal generation array in which weights having data values for generating a replica MAC reference signal having a voltage difference of ½ LSB (Least Significant Bit) from the replica MAC signal are stored.

In the MAC signal generation array, a weight having a data value of 0 may be stored in the replica cell so that the replica MAC signal has the minimum possible voltage level.

In the replica reference signal generation array, a weight of a data value that causes the replica MAC reference signal to have a voltage level that is ½ LSB higher than that of the replica MAC signal may be stored in the replica cell.

The refresh determination module may activate the refresh enable signal when the voltage level of the replica MAC signal becomes higher than the voltage level of the replica MAC reference signal.

In the MAC signal generation array, a weight having a data value of 1 may be stored in the replica cell so that the replica MAC signal has the maximum possible voltage level.

In the replica reference signal generation array, a weight of a data value that causes the replica MAC reference signal to have a voltage level that is ½ LSB lower than that of the replica MAC signal may be stored in the replica cell.

The refresh determination module may activate the refresh enable signal when the voltage level of the replica MAC signal becomes lower than the voltage level of the replica MAC reference signal.

In the replica reference signal generation array, weights having data values for generating a replica MAC reference signal having a voltage difference of ½ LSB from the replica MAC signal may be measured and stored in advance.

The replica cell may be implemented to have the same structure as the memory cell, but to have a capacitance less than the capacitance of the memory cell.

According to another embodiment of the present disclosure, a method for adaptively adjusting refresh timing of a CIM based on eDRAM, performed by an apparatus for adjusting refresh timing including a replica array including a plurality of replica MAC arrays, each having replica cells arranged in a direction and number according to the direction and number in which memory cells performing MAC operations together in a CIM cell array are arranged and a refresh determination module, includes the steps of: each of the plurality of replica MAC arrays outputting a signal according to a MAC operation result according to a weight stored in each replica cell; and comparing voltage levels of signals output from each of the plurality of replica MAC arrays and activating a refresh enable signal for refreshing memory cells of the CIM cell array.

The apparatus and method for adaptively adjusting refresh timing of a CIM based on eDRAM of the present disclosure detects whether a MAC operation error is likely to occur based on a replica array and generates a refresh command, thereby adaptively adjusting the refresh timing so that an error does not occur in the MAC operation result.

### BRIEF DESCRIPTION OF THE DRAWINGS

FIG. 1 shows a schematic structure of a CIM according to an embodiment of the present disclosure.

FIG. 2 is a diagram for explaining the concept of a MAC operation and the method of performing a MAC operation in a CIM according to an embodiment of the present disclosure.

FIGS. 3 to 5 are diagrams for explaining differences in the detection method of a CIM according to a memory cell and a domain according to an embodiment of the present disclosure.

FIGS. 6 to 8 are diagrams for explaining differences in data retention time according to data stored in a memory cell and MAC operation errors according to an embodiment of the present disclosure.

FIG. 9 shows the results of simulating the differences in memory retention time and MAC operation retention time according to an embodiment of the present disclosure.

FIG. 10 shows a schematic structure of an apparatus for adaptively adjusting refresh timing according to an embodiment of the present disclosure.

FIG. 11 shows a method for adaptively adjusting refresh timing according to an embodiment of the present disclosure.

### DETAILED DESCRIPTION OF THE INVENTION

Hereinafter, specific embodiments according to the embodiments of the present disclosure will be described with reference to the drawings. The following detailed description is provided to assist in a comprehensive understanding of the methods, devices and/or systems described herein. However, this is only an example, and the present invention is not limited thereto.

In describing the embodiments of the present disclosure, when it is determined that detailed descriptions of known technology related to the present disclosure may unnecessarily obscure the gist of the embodiments, the detailed descriptions thereof will be omitted. The terms used below are defined in consideration of functions in the present disclosure but may be changed depending on the customary practice or the intention of a user or operator. Thus, the definitions should be determined based on the overall content of the present specification. The terms used herein are only for describing the embodiments and should not be construed as limitative. Unless the context clearly indicates otherwise, the singular forms are intended to include the plural forms as well. It should be understood that the terms “comprises,” “comprising,” “includes,” and “including,” when used herein, specify the presence of stated features, numerals, steps, operations, elements, or combinations thereof, but do not preclude the presence or addition of one or more other features, numerals, steps, operations, elements, or combinations thereof. In addition, terms such as “ . . . unit”, “ . . . er/or”, “module” and “block” described in the specification means a unit for processing at least one function or operation, which may be implemented by hardware or software or a combination of hardware and software.

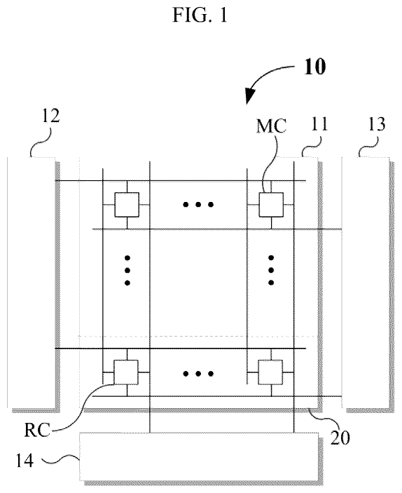

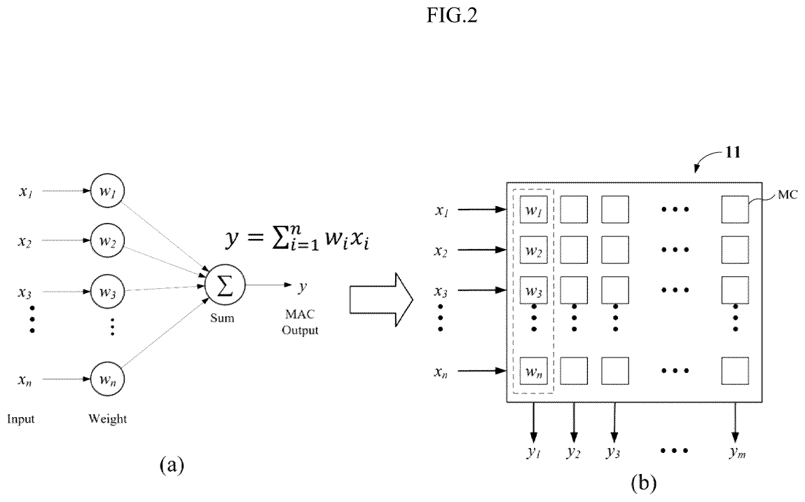

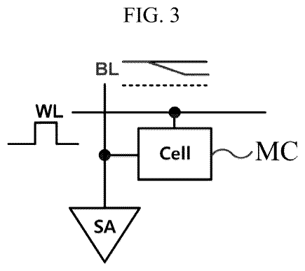

FIG. 1 shows a schematic structure of a CIM according to an embodiment of the present disclosure, FIG. 2 is a diagram for explaining the concept of a MAC operation and the method of performing a MAC operation in a CIM, and FIGS. 3 to 5 are diagrams for explaining differences in the detection method of a CIM according to a memory cell and a domain according to an embodiment of the present disclosure.

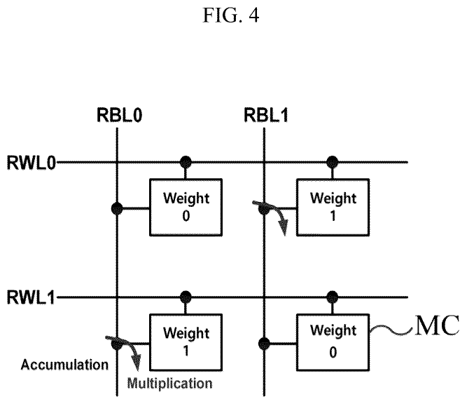

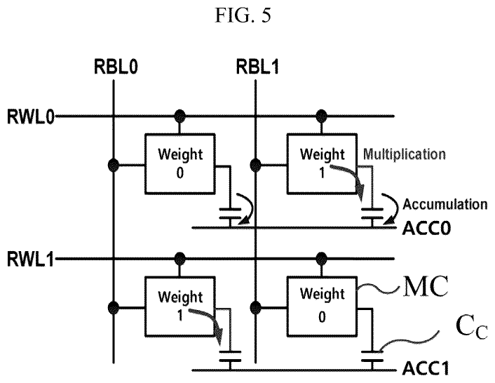

In FIG. 2, (a) is a drawing for explaining the concept of MAC operation, and (b) of FIG. 2 is a drawing for explaining the method of performing MAC operation in CIM. In addition, FIG. 3 shows an example of a structure for reading data stored in a memory cell (MC), and FIGS. 4 and 5 show an example of a CIM structure for detecting MAC results in the current and charge domains, respectively.

Referring to FIG. 1, a CIM 10 according to an embodiment may include a CIM cell array 11, an analog conversion module 12, a digital conversion module 13, and a read/write module 14.

The analog conversion module 12 receives input data, which is digital data, and converts the input data into an input signal x having a voltage level according to the data value and applies the same to the CIM cell array 11. Here, the analog conversion module 12 may simultaneously apply a plurality of input signals x₁, x₂, . . . , xₙ according to a plurality of input data to the CIM cell array 11. The analog conversion module 12 may be implemented with a DAC (Digital Analog Converter), etc., or with a decoder that activates a line (e.g., a word line WL) for selecting a memory cell MC of the CIM cell array 11 according to the input data.

The CIM cell array 11 includes a plurality of arranged memory cells MC. Here, each of the plurality of memory cells MC may be implemented with an eDRAM as described above. As shown in (b) of FIG. 2, a plurality of weights w₁, w₂, . . . , wₙ set by learning of artificial neural network may be stored in each of the plurality of memory cells MC. In addition, in each memory cell MC, the input signal x₁, x₂, . . . , xₙ applied from the analog conversion module 12 and the stored weight w are multiplied. The CIM cell array 11 generates a MAC signal, which is an analog signal in which the multiplication result between the input signal x₁, x₂, . . . , xₙ and the stored weight w₁, w₂, . . . , wₙ is accumulated, and transmits it to the digital conversion module 13.

As shown in (a) of FIG. 2, the MAC operation is performed in such a way that the corresponding input signals and weights among a plurality of input signals x₁, x₂, . . . , xₙ and a plurality of weights w₁, w₂, . . . , wₙ are multiplied, and the multiplication results between each input signal and weight are all summed. The MAC operation can be expressed in Equation as y=Σᵢ₌₁ⁿwᵢxᵢ.

As shown in (b) of FIG. 2, a plurality of weights w₁, w₂, . . . , wₙ are stored in advance in each of a plurality of memory cells MC of the CIM cell array 11. Then, among the plurality of memory cells MC of the CIM cell array 11, a memory cell is selected on which a MAC operation with a plurality of input signals x₁, x₂, . . . , xₙ applied from the analog conversion module 12 is to be performed. At this time, the memory cell MC may be selected by the control of a memory controller (not shown), and depending on the domain representing the structure of the CIM 10 and the MAC operation method performed in the CIM 10, a plurality of memory cells MC arranged in a row or column direction (column direction as an example in FIG. 2) may be selected together.

Once a plurality of input signals x₁, x₂, . . . , xₙ are applied from the analog conversion module 12, a multiplication operation between the input signal corresponding to the stored weight and the weight is performed in each of the selected memory cells MC, and the voltage or current according to the result of the multiplication operation performed in each of the plurality of memory cells MC is applied to an accumulation line commonly connected to the selected memory cell MC. Here, the accumulation line may be implemented as read bit lines RBL0 and RBL1 as shown in FIG. 4 when the CIM 10 operates as a current domain that detects the MAC operation result based on the current. However, when the CIM 10 operates as a charge domain that detects the MAC operation result by accumulating the voltage applied from the selected memory cell MC through the coupling capacitor Cc as shown in FIG. 5, it may be implemented as separate accumulation lines ACC0 and ACC1. In each accumulation line, a MAC signal y is generated by accumulating the result of multiplication between the input signal and the weight performed in the plurality of memory cells MC. The generated MAC signal y is transmitted to the digital conversion module 13.

Meanwhile, the digital conversion module 13 receives the MAC signal y that appears as a result of the MAC operation performed on the CIM cell array 11, converts it into digital data, and outputs the MAC operation data. The digital conversion module 13 detects the voltage level of the MAC signal y, which is the result of the CIM cell array 11 performing the MAC operation on a plurality of input signals x₁, x₂, . . . , xₙ and a plurality of weights w₁, w₂, . . . , wₙ in an analog manner, and converts it into a digital signal, MAC operation data, and outputs it. Here, the digital conversion module 13 may be implemented as an ADC (Analog Digital Converter), etc.

The read/write module 14 may read weights w₁, w₂, . . . , wₙ stored in a plurality of memory cells MC in the CIM cell array 11, or write and store weights in a plurality of memory cells MC. Here, the read/write module 14 may be implemented by including a sense amplifier SA as shown in FIG. 3. The sense amplifier SA detects and amplifies a voltage level change of a bit line BL (or a read bit line RBL) according to the value of data stored in the memory cell MC, and outputs it as digital data. The read/write module 14 may also be configured to be integrated with the digital conversion module 13 depending on the structure of the CIM 10.

Meanwhile, the CIM 10 of the present disclosure may further include a replica array 20 for detecting a MAC DRT (DRT_{MAC}) indicating a time for which a MAC operation result is maintained in response to a memory DRT (DRT_{memory}), which is a time for which data is maintained in a memory cell MC.

The replica array 20 includes two or more replica MAC arrays, each having replica cells RC arranged in the same direction and number as the direction and number of memory cells MC arranged to perform MAC operations together among the plurality of memory cells MC of the CIM cell array 11. As an example, as shown in (b) of FIG. 2, if n memory cells MC arranged in the column direction in the CIM cell array 11 are configured to perform MAC operations together, each of the two or more replica MAC arrays may be configured as a replica column including n replica cells RC arranged in the column direction. However, if memory cells MC arranged in the row direction in the CIM cell array 11 are configured to perform MAC operations, each of the two or more replica MAC arrays may be configured as a replica row.

In addition, the replica cell RC has the same structure as the memory cell MC of the CIM cell array 11, but has a capacitance smaller than the capacitance C_{SN} of the storage node SN of the memory cell MC. Since the replica cell RC is implemented to have only a smaller capacitance in the same structure as the memory cell MC, the replica cell RC may be configured together when configuring the CIM cell array 11. In addition, the replica cell RC may be connected by extending the read bit line RBL or the write bit line WBL connected to the memory cell MC. Therefore, the replica array 20 may also be formed by extending the CIM cell array 11 to one side.

That is, the replica cell RC also uses the read bit line RBL or write bit line WBL of the memory cell MC in common, so that data can be read or written in the same manner as the memory cell MC.

Meanwhile, in the case of two replica MAC arrays, one may operate as a replica reference signal generation array that generates a replica MAC reference signal, and the other one may operate as a replica MAC generation array that generates a replica MAC signal. In addition, in the case of four replica MAC arrays, two may operate as the first and second replica reference signal generation arrays, and the other two may operate as the first and second replica MAC signal generation arrays.

The replica MAC array of the replica array 20 will be described in detail below.

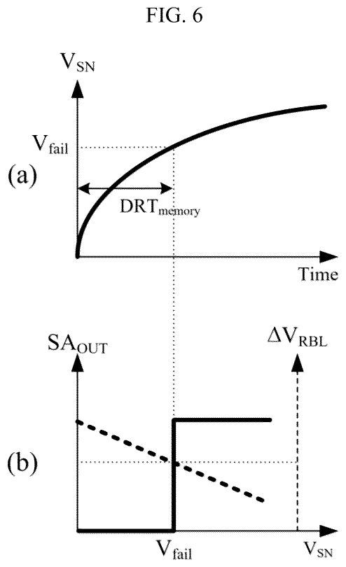

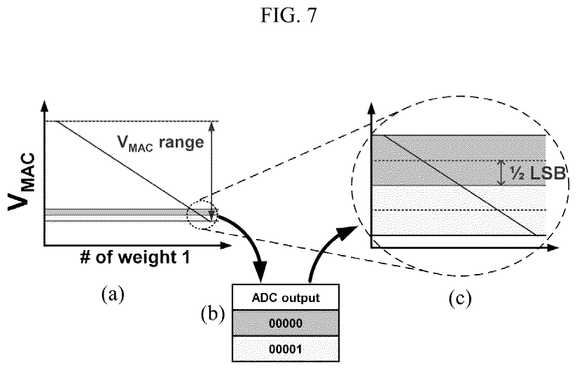

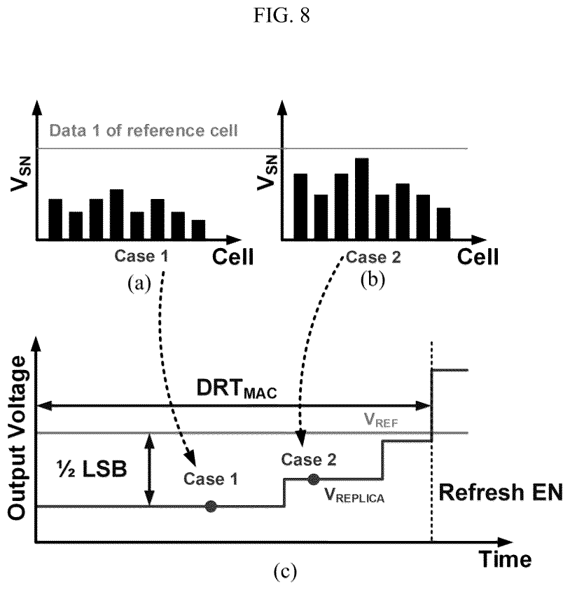

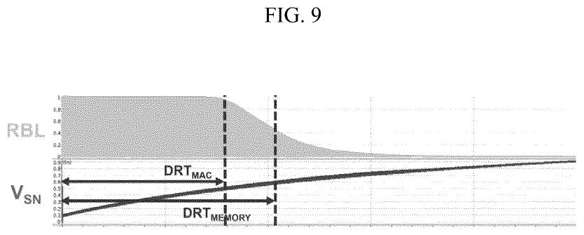

FIGS. 6 to 8 are diagrams for explaining differences in data retention time according to data stored in a memory cell and MAC operation errors. Specifically, FIG. 6 is a drawing for explaining memory DRT (DRT_{memory}) according to data stored in a memory cell, FIG. 7 is a drawing for explaining the voltage range where MAC operation error occurs, and FIG. 8 is a drawing for explaining MAC DRT (DRT_{MAC}) according to MAC operation error. In addition, FIG. 9 shows the results of simulating the differences in memory retention time and MAC operation retention time.

In FIG. 6, (a) shows the change in voltage V_{SN} of the storage node SN of the memory cell MC over time, and (b) shows the read bit line voltage difference V_{RBL} of the read circuit and the change in the sense amplifier SA output SA_{OUT} according to the change in voltage V_{SN} of the storage node SN of the memory cell MC.

FIG. 6 illustrates an example where a storage node SN of a memory cell MC has a designated low voltage level (e.g., a ground voltage V_{SS} level) according to the stored data. Depending on the structure of the memory cell including the CIM, it may be set to have a low voltage level when the stored data value is 0, or a low voltage level when it is 1. Here, it is assumed that the storage node SN is set to have a low voltage level when the data value is 0. Therefore, (a) of FIG. 6 shows a case in which data having a value of 0 is stored in the memory cell MC.

When data 0 is stored in the memory cell MC, and as shown in (a) of FIG. 6, the voltage level of the storage node SN is at a low level, the voltage level of the storage node SN is not maintained due to leakage over time and gradually increases. When the voltage level of the storage node SN increases, the read bit line voltage difference V_{RBL}, which indicates the voltage level change of the read bit line RBL during the read operation, gradually decreases as shown in the straight line indicated by the thick dotted line in (b) of FIG. 6. However, when the read bit line voltage difference V_{RBL} is greater than a certain size, the output SA_{OUT} of the sense amplifier SA that detects the data value of the memory cell MC does not change.

As time passes after data is stored, the voltage level of the storage node SN increases further, and the read bit line voltage difference V_{RBL} continues to decrease. In addition, when the decreasing read bit line voltage difference V_{RBL} decreases below a discriminant criterion of the sense amplifier SA, an error occurs in which the sense amplifier SA detects the data value stored in the memory cell MC as 1 instead of 0 and outputs it. In other words, the sense amplifier SA detects that the value of the data stored in the memory cell MC has changed, and changes the output SA_{OUT}.

Conversely, when data having a value of 1 is stored in the memory cell MC, and the voltage of the storage node SN is at a set high level (e.g., the power supply voltage V_{DD} level), the voltage level of the storage node SN gradually decreases, which gradually increases the read bit line voltage difference V_{RBL}, and the sense amplifier SA may detect incorrectly and output the data value stored in the memory cell MC as 0 instead of 1.

In this way, the time from when data is stored in a memory cell MC until the data detected by the sense amplifier SA changes from normal data to error data is the memory DRT (DRT_{memory}), and existing eDRAM-based memory devices including CIM set the refresh time to perform a refresh before reaching the memory DRT (DRT_{memory}).

Meanwhile, CIM 10 is mainly used to perform MAC operation, and therefore, it is very important in CIM to obtain accurate MAC operation results as well as the values of the data stored in each of a plurality of memory cells MC. Since the weights w₁, w₂, . . . , wₙ stored in the memory cells MC are ultimately operands for performing MAC operation, it is most important in CIM 10 that not only the weights w₁, w₂, . . . , wₙ but also the MAC operation result with the input signals x₁, x₂, . . . , xₙ is normally output.

As shown in FIGS. 4 and 5, the MAC signal in the CIM is a signal obtained by an analog operation method in which the voltage or current resulting from the multiplication of the input signal x₁, x₂, . . . , xₙ and the weight w₁, w₂, . . . , wₙ from a plurality of memory cells MC is applied to the accumulation line (RBL or ACC) commonly connected to the selected memory cells MC and added. Then, the obtained MAC signal must be converted into a digital signal in the digital conversion module 13 composed of an ADC, etc. At this time, unlike a sense amplifier SA that discriminates a 1-bit data value of 0 or 1, the digital conversion module 13 discriminates the value of the MAC signal by dividing the voltage range (V_{MAC} range) that the MAC signal can have into a number of levels (for example, 2⁵=32) according to the number of bits (n, for example, n=5) set according to the required bit resolution, as shown in FIG. 7 (a).

In FIG. 7, (a) separately shows only the ranges of the lower two levels in the voltage range (V_{MAC} range) divided into 2ⁿ sections, (b) shows the data values (here, 00000, 00001 as an example) when the MAC signal is included in the lower two levels, and (c) is a drawing showing the ranges of the lower two levels in (a) expanded.

If the sense amplifier SA discriminates the voltage range that the read bit line voltage difference V_{RBL} can have by dividing it into two levels based on one boundary as shown in (b) of FIG. 6, the ADC of the digital conversion module 13 determines the voltage range (V_{MAC} range) that the MAC signal can have by dividing it into 32 sections according to the set number of bits n. Although the voltage range that the read bit line voltage difference V_{RBL} can have is very small compared to the voltage range (V_{MAC} range) that the MAC signal can have, as shown in (a) of FIG. 7, since the interval between each section that the digital conversion module 13 divides the voltage range (V_{MAC} range) of the MAC signal is smaller, it can be seen that the digital conversion module 13 reacts more sensitively to the MAC signal than the sense amplifier SA.

In particular, if the level of the MAC signal occurs to be greater than ½ of the level difference according to the Least Significant Bit (hereinafter “LSB”) in each section, that is, greater than ½ LSB, the digital conversion module 13 will generate a MAC operation error. For example, in (b) of FIG. 7, the MAC signal is included in the lowest level, and an error may occur in which the ADC of the digital conversion module 13 outputs a data value of 00001 even though it should output a data value of 00000. In other words, the accumulated value of the voltage V_{SN} change of the storage node SN of a plurality of memory cells MC selected together to perform the MAC operation should not exceed ½ LSB.

In addition, as shown in (a) and (b) of FIG. 8, the voltage V_{SN} of the storage node SN of each of the plurality of memory cells MC may be different from each other. In addition, as shown in (c) of FIG. 8 as Case 1 and Case 2, the MAC signal has a voltage level that accumulates the multiplication results in the plurality of memory cells MC. Therefore, even if the voltage of the storage node SN changes abruptly only in some of the plurality of memory cells MC selected to perform the MAC operation, the MAC operation result may be changed.

Accordingly, the memory DRT (DRT_{memory}), which indicates whether the data value of the memory cell MC changes, and the MAC DRT (DRT_{MAC}), which indicates the time for which the MAC operation result is maintained, are compared as shown in FIG. 9. Referring to FIG. 9, it can be seen that the MAC DRT (DRT_{MAC}) is much shorter than the memory DRT (DRT_{memory}) (DRT_{MAC}<<DRT_{memory}). As a result, if the refresh time of the memory cell MC in the CIM is set to the existing memory DRT (DRT_{memory}), no error occurs in the value of the data stored in the memory cell MC, but an error occurs in the MAC operation result of the CIM. In order to prevent this problem from occurring, the CIM 10 must adjust the refresh timing based on the MAC DRT (DRT_{MAC}), not the memory DRT (DRT_{memory}).

There has been no proposal for a method to adjust the refresh timing based on the MAC DRT (DRT_{MAC}) in the past. Accordingly, in the present disclosure, a replica MAC DRT (DRT_{MAC.REP}) is generated and detected using the replica array (20) illustrated in FIG. 1, and the refresh timing for the memory cell MC of the CIM cell array 11 is adjusted based on the replica MAC DRT (DRT_{MAC.REP}).

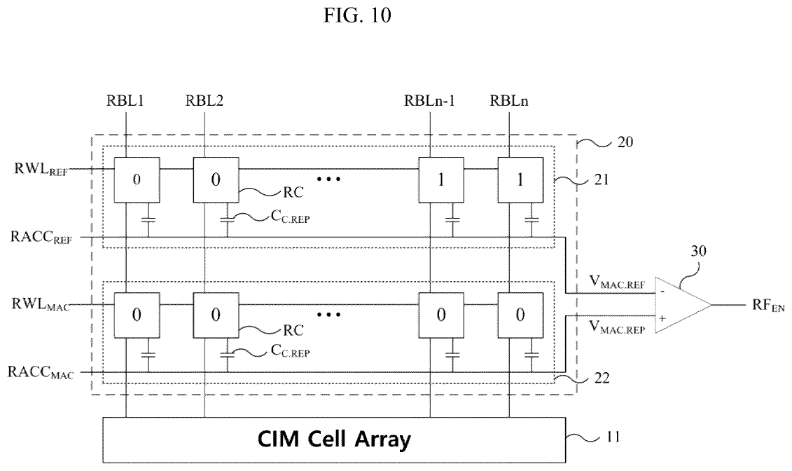

FIG. 10 shows a schematic structure of an apparatus for adaptively adjusting refresh timing according to an embodiment.

Referring to FIG. 10, an apparatus for adaptively adjusting refresh timing according to an embodiment may include a replica array 20 including a plurality of replica cells RC, and a refresh determination module.

As described above, the replica array 20 includes two or more replica MAC arrays, each of which has replica cells RC arranged in the same direction and number as the direction and number of memory cells arranged to perform MAC operations together in the CIM cell array 11.

Here, as an example, two replica MAC arrays 21 and 22 each having n replica cells RC arranged in a row direction are illustrated. In FIG. 10, a plurality of read bit lines RBL1 to RBLn may be lines formed by extending the read bit lines RBL1 to RBLn of the CIM cell array 11, while the read word line RWL may be a line additionally formed to select the replica cells RC of the replica MAC arrays 21 and 22.

In addition, as shown in FIG. 5, it is assumed that the CIM 10 is a charge domain-based CIM 10 in which the voltage obtained by multiplying the input signal x₁, x₂, . . . , xₙ and the weight w₁, w₂, . . . , wₙ from a plurality of selected memory cells MC is accumulated on the accumulation lines ACC0 and ACC1 through the coupling capacitor Cc to generate the MAC signal. Accordingly, the replica MAC arrays 21 and 22 are also illustrated as each having a replica accumulation line RACC, and a plurality of replica coupling capacitors C_{C.REP} that transmit the voltage applied from a plurality of replica cells RC to the replica accumulation line RACC.

In FIG. 10, one of the two replica MAC arrays 21 and 22 is a replica reference signal generation array 21 that generates a replica MAC reference signal, and the other one is a replica MAC signal generation array 22 that generates a replica MAC signal.

Hereinafter, for convenience of understanding, the replica accumulation line RACC and the read word line RWL of the replica reference signal generation array 21 are referred to as the reference replica accumulation line RACC_{REF} and the reference read word line RWL_{REF}, and the replica accumulation line RACC and the read word line RWL of the replica MAC signal generation array 22 are referred to as the MAC replica accumulation line RACC_{MAC} and the MAC read word line RWL_{REF}.

The replica reference signal generation array 21 and the replica MAC signal generation array 22 have the same configuration, but may be distinguished according to the value of the weight w stored in the replica cell RC.

Specifically, weights w having the same data value are stored in a plurality of replica cells RC included in the replica MAC signal generation array 22 so that the voltage V_{MAC.REP} of the replica MAC signal has the minimum voltage level Min (V_{MAC.REP}) (or the maximum voltage level Max (V_{MAC.REP})) that it can have. In other words, weights w corresponding to the) maximum fluctuation range Max (V_{MAC.REP}) of the replica MAC signal are stored. This is to ensure that the voltage V_{MAC.REP} of the replica MAC signal becomes the maximum or minimum value when converted to multi-bit digital data. Here, as an example, a case is illustrated where weights w having a data value of 0 are stored in all replica cells RC of the replica MAC signal generation array 22 so that the replica MAC signal has the minimum voltage level Min (V_{MAC.REP}).

In addition, in the plurality of replica cells RC of the replica reference signal generation array 21, the weight w of the data value is stored that makes the voltage level V_{MAC.REF} of the replica MAC reference signal different from the voltage V_{MAC.REP} of the replica MAC signal by a voltage corresponding to ½ LSB when converted to multi-bit digital data. Here, the data value of the weight w that causes the difference to be equal to the voltage corresponding to ½ LSB may be changed in various ways depending on the number of replica cells RC included in the replica reference signal generation array 21, the configuration of the digital conversion module 13, etc. Therefore, the weight w stored in the plurality of replica cells RC of the replica reference signal generation array 21 may be measured and determined in advance using an ADC of the digital conversion module 13, etc.

The refresh determination module may include at least one comparator 30. The comparator 30 may receive a replica MAC reference signal via a negative input terminal and receive a replica MAC signal via a positive input terminal to output a refresh enable signal RF_{EN}.

Here, a case is illustrated, where since the weights w having a data value of 0 are stored in all replica cells RC of the replica MAC signal generation array 22, and the replica MAC signal has a minimum voltage level Min (V_{MAC.REP}), the weights w having a data value of 1 are stored in only two replica cells RC among the n replica cells RC of the replica reference signal generation array 21, and the weights w having a data value of 0 are stored in the remaining replica cells RC.

Therefore, the replica MAC reference signal output from the replica reference signal generation array 21 has a voltage level that is ½ LSB higher than the voltage V_{MAC.REP} of the replica MAC signal. Accordingly, the comparator 30 deactivates and outputs the refresh enable signal RF_{EN}.

Thereafter, when the voltage V_{MAC.REP} level of the replica MAC signal output from the replica MAC signal generation array 22 fluctuates over time, and thus the voltage level of the voltage V_{MAC.REP} of the replica MAC signal becomes higher than the voltage level of the replica MAC reference signal, the comparator 30 activates and outputs the refresh enable signal RF_{EN}.

When the refresh enable signal RF_{EN} is activated, a memory controller (not shown) performs a refresh operation on a plurality of memory cells MC of the CIM cell array 11.

As a result, in the present disclosure, the MAC DRT (DRT_{MAC}) refresh timing is adaptively adjusted based on the MAC operation result of the replica array 20 composed of replica cells RC, not the data stored in the memory cell MC in the CIM 10. At this time, since the capacitance of the replica cell RC is smaller than the capacitance of the memory cell MC, if adjusting the refresh timing based on the MAC operation result of the replica cell RC, no error occurs in the MAC operation result for the memory cell MC of the CIM cell array 11.

In the above, it was described that a weight w having a data value of 0 is stored in all replica cells RC of the replica MAC signal generation array 22, and the weight w that makes the replica MAC reference signal have a voltage level that is ½ LSB higher than the voltage V_{MAC.REP} of the replica MAC signal is stored in the replica reference signal generation array 21. However, the weight w having a data value of 1 may be stored in all replica cells RC of the replica MAC signal generation array 22, and the weight w that makes the replica MAC reference signal have a voltage level that is ½ LSB lower than the voltage V_{MAC.REP} of the replica MAC signal may be stored in the replica reference signal generation array 21. As an example, the replica reference signal generation array 21 may store weights of 0 in only two replica cells RC, and store weights of 1 in all the rest.

In addition, the replica array 20 may have four replica MAC arrays. That is, it may have first and second replica reference signal generation arrays and first and second replica MAC generation arrays. In this case, all replica cells RC of the first replica MAC generation array may store weights of 0, so that a first replica MAC signal having a minimum voltage level Min (V_{MAC.REP}) may be generated, and all replica cells RC of the second replica MAC generation array may store weights of 1, so that a second replica MAC signal having a maximum voltage level Max (V_{MAC.REP}) may be generated.

In addition, the first replica reference signal generation array may store a weight w that allows a voltage level to be ½ LSB higher than that of the first replica MAC signal in a plurality of replica cells RC, so that the first replica MAC reference voltage may be generated, and the second replica reference signal generation array may store a weight w that allows a voltage level to be ½ LSB lower than that of the second replica MAC signal in a plurality of replica cells RC, so that the second replica MAC reference voltage may be generated.

When the replica array 20 has four replica MAC arrays, the refresh determination module may include two comparators and one logical OR gate (NOR). The two comparators compare the first replica MAC signal with the first replica MAC reference voltage, and compare the second replica MAC signal with the second replica MAC reference voltage, respectively, to output the comparison result. The logical OR gate (NOR) may activate the refresh enable signal RF_{EN} by performing logical OR of the comparison results output from the two comparators.

The reason why the replica array 20 has four replica MAC arrays like this is because the MAC DRT (DRT_{MAC}) may be different depending on the data values of the weights w stored in the replica cells RC of the replica MAC generation array.

Meanwhile, in FIG. 10, the replica array 20 is illustrated as including replica MAC arrays 21 and 22, each having n replica cells RC arranged in the row direction. However, as illustrated in FIG. 4, depending on the CIM 10, a plurality of memory cells MC arranged in the column direction may be configured to perform MAC operations. In this case, the replica array 20 may include two or more replica MAC arrays 21 and 22, each having a plurality of replica cells RC arranged in the column direction. In addition, as in FIG. 4, when the read bit line RBL is used as an accumulation line during the MAC operation, the replica accumulation line RACC and replica coupling capacitor C_{C.REP} illustrated in FIG. 10 may be omitted, and instead, a replica read bit line may be further formed.

In the illustrated embodiment, respective configurations may have different functions and capabilities in addition to those described above, and may include additional configurations in addition to those described above. In addition, in an embodiment, each configuration may be implemented using one or more physically separated devices, or may be implemented by one or more processors or a combination of one or more processors and software, and may not be clearly distinguished in specific operations unlike the illustrated example.

In addition, the apparatus for adaptively adjusting refresh timing shown in FIG. 10 may be implemented in a logic circuit by hardware, firmware, software, or a combination thereof or may be implemented using a general purpose or special purpose computer. The apparatus may be implemented using hardwired device, field programmable gate array (FPGA) or application specific integrated circuit (ASIC). Further, the apparatus may be implemented by a system on chip (SoC) including one or more processors and a controller.

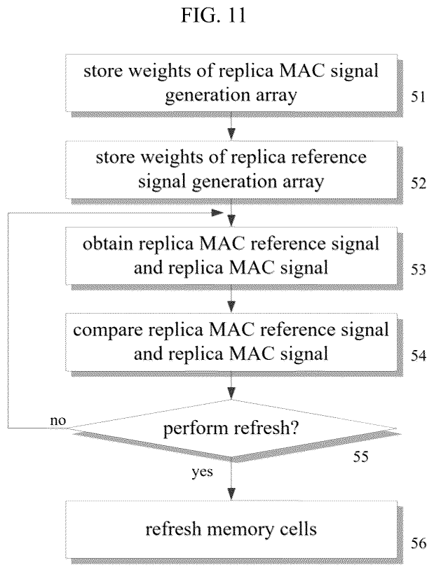

FIG. 11 shows a method for adaptively adjusting refresh timing according to an embodiment.

Referring to FIG. 10, the method for adaptively adjusting refresh timing of FIG. 11 will be described. First, weights w of the same data value (0 or 1) are stored in the replica cells RC so that the replica MAC signal generation array 22, among a plurality of replica MAC arrays, each having replica cells RC arranged in the same direction and number as the direction and number of memory cells MC arranged to perform MAC operations together in the CIM cell array 11, generates a replica MAC signal of the minimum voltage level Min (V_{MAC.REP}) (or the maximum voltage level Max (V_{MAC.REP})) (51).

Here, the replica cell RC may have the same structure as the memory cell MC, but may have less capacitance.

Then, a weight w of the data value for generating a replica MAC reference signal having a voltage difference corresponding to ½ LSB from the replica MAC signal generated in the replica MAC signal generation array 22 is stored in the replica reference signal generation array 21 among the plurality of replica MAC arrays (52). Here, the weight for generating the replica MAC reference signal having a voltage difference corresponding to ½ LSB from the replica MAC signal may be designated in advance through measurement.

Once the designated weights are stored in each of the plurality of replica cells RC of the replica reference signal generation array 21 and the replica MAC signal generation array 22, the replica cells RC included in the replica reference signal generation array 21 and the replica MAC signal generation array 22 are selected to obtain the replica MAC reference signal generated from the replica reference signal generation array 21 and the replica MAC signal generated from the replica MAC signal generation array 22 (53).

Then, the voltage levels of the obtained replica MAC reference signal and the replica MAC signal are compared (54). Whether to perform a refresh is determined using the result of comparing the voltage levels of the replica MAC reference signal and the replica MAC signal (55). In other words, it determines whether the voltage according to the data stored in the replica cells RC has changed due to leakage and reached MAC DRT (DRT_{MAC}), which causes a change in the MAC operation result.

If it is determined that a refresh is required, the data stored in a plurality of memory cells MC included in the CIM cell array 11 is refreshed (56). However, if it is determined that a refresh is not required because the MAC DRT (DRT_{MAC}) is not reached, the replica MAC reference signal and the replica MAC signal are obtained again (53).

In FIG. 11, it is described that respective processes are sequentially executed, which is, however, illustrative, and those skilled in the art may apply various modifications and changes by changing the order illustrated in FIG. 11 or performing one or more processes in parallel or adding another process without departing from the essential gist of the exemplary embodiment of the present disclosure.

The present disclosure has been described in detail through a representative embodiment, but those of ordinary skill in the art to which the art pertains will appreciate that various modifications and other equivalent embodiments are possible from this. Therefore, the true technical protection scope of the present invention should be determined by the technical spirit set forth in the appended scope of claims.

What is claimed is:

1. An apparatus for adjusting refresh timing, including:
a replica array including a plurality of replica Multi-Accumulate (MAC) arrays, each having replica cells arranged in a direction and number according to the direction and number in which memory cells performing MAC operations together in a Computer-In-Memory (CIM) cell array are arranged; and
a refresh determination module that compares voltage levels of signals output from each of the plurality of replica MAC arrays with MAC operation results according to weights stored in replica cells of the plurality of replica MAC arrays and activates a refresh enable signal for refreshing memory cells of the CIM cell array.

2. The apparatus for adjusting refresh timing according to claim 1,
wherein
the plurality of replica MAC arrays include a replica MAC signal generation array in which weights of the same data values are stored in all of the replica cells to generate a replica MAC signal and a replica reference signal generation array in which weights having data values for generating a replica MAC reference signal having a voltage difference of ½ LSB (Least Significant Bit) from the replica MAC signal are stored.

3. The apparatus for adjusting refresh timing according to claim 2,
wherein, in the replica MAC signal generation array,
a weight having a data value of 0 is stored in the replica cells so that the replica MAC signal has the minimum possible voltage level.

4. The apparatus for adjusting refresh timing according to claim 3,
wherein, in the replica reference signal generation array,
a weight of a data value that causes the replica MAC reference signal to have a voltage level that is ½ LSB higher than the voltage level of the replica MAC signal is stored in the replica cell.

5. The apparatus for adjusting refresh timing according to claim 4,
wherein the refresh determination module activates the refresh enable signal when the voltage level of the replica MAC signal becomes higher than the voltage level of the replica MAC reference signal.

6. The apparatus for adjusting refresh timing according to claim 2,
wherein, in the replica MAC signal generation array,
a weight having a data value of 1 is stored in the replica cells so that the replica MAC signal has the maximum possible voltage level.

7. The apparatus for adjusting refresh timing according to claim 6,
wherein, in the replica reference signal generation array,
a weight of a data value that causes the replica MAC reference signal to have a voltage level that is ½ LSB lower than the voltage level of the replica MAC signal is stored in the replica cells.

8. The apparatus for adjusting refresh timing according to claim 7,
wherein the refresh determination module activates the refresh enable signal when the voltage level of the replica MAC signal becomes lower than the voltage level of the replica MAC reference signal.

9. The apparatus for adjusting refresh timing according to claim 2,
wherein, in the replica reference signal generation array,
weights having data values for generating a replica MAC reference signal having a voltage difference of ½ LSB from the replica MAC signal are measured and stored in advance.

10. The apparatus for adjusting refresh timing according to claim 1,
wherein the replica cells are implemented to have the same structure as the memory cells, but to have a capacitance less than the capacitance of the memory cells.

11. A method for adjusting refresh timing, performed by an apparatus for adjusting refresh timing including a replica array including a plurality of replica MAC arrays, each having replica cells arranged in a direction and number according to the direction and number in which memory cells performing MAC operations together in a CIM cell array are arranged and a refresh determination module, the method including the steps of:
each of the plurality of replica MAC arrays outputting a signal according to a MAC operation result according to a weight stored in each replica cell; and
comparing voltage levels of signals output from each of the plurality of replica MAC arrays and activating a refresh enable signal for refreshing memory cells of the CIM cell array.

12. The method for adjusting refresh timing according to claim 11,
wherein, in the step of outputting a signal,
a replica MAC signal generation array, in which weights of the same data values are stored in all of the replica cells, among the plurality of replica MAC arrays generates a replica MAC signal, and
a replica reference signal generation array among the plurality of replica MAC arrays generates a replica MAC reference signal having a voltage difference of ½ LSB (Least Significant Bit) from the replica MAC signal, according to weights stored in the replica cells.

13. The method for adjusting refresh timing according to claim 12,
wherein, in the step of outputting a signal,
the replica MAC signal generation array generates the replica MAC signal having the minimum possible voltage level according to weights stored in the replica cells.

14. The method for adjusting refresh timing according to claim 13,
wherein, in the step of outputting a signal,
the replica reference signal generation array generates the replica MAC reference signal having a voltage level that is ½ LSB higher than the voltage level of the replica MAC signal.

15. The method for adjusting refresh timing according to claim 14,
wherein the step of activating a refresh enable signal includes activating the refresh enable signal when the voltage level of the replica MAC signal becomes higher than the voltage level of the replica MAC reference signal.

16. The method for adjusting refresh timing according to claim 12,
wherein, in the step of outputting a signal,
the replica MAC signal generation array generates the replica MAC signal having the maximum possible voltage level according to weights stored in the replica cells.

17. The method for adjusting refresh timing according to claim 16,
wherein, in the step of outputting a signal,
the replica reference signal generation array generates the replica MAC reference signal having a voltage level that is ½ LSB lower than the voltage level of the replica MAC signal.

18. The method for adjusting refresh timing according to claim 16,
wherein the step of activating a refresh enable signal includes activating the refresh enable signal when the voltage level of the replica MAC signal becomes lower than the voltage level of the replica MAC reference signal.

19. The method for adjusting refresh timing according to claim 12,
wherein, in the method for adjusting refresh timing,
weights of the replica MAC signal generation array and weights of the replica reference signal generation array for generating a replica MAC reference signal having a voltage difference of ½ LSB from the replica MAC signal are determined and stored in advance.

20. The method for adjusting refresh timing according to claim 11,
the replica cells have the same structure as the memory cells, but have a capacitance less than the capacitance of the memory cells.
